(19) United States
(12) Patent Application Publication
(10) Pub. No.: US 2025/0266238 A1
(43) Pub. Date: Aug. 21, 2025

(54) MODULAR MINIATURE CHARGED PARTICLE BEAM COLUMN

(71) Applicant: Multibeam Corporation, Santa Clara, CA (US)

(72) Inventors: Eli Vronsky, Santa Clara, CA (US); Randy Hall, Santa Clara, CA (US); Justin Fortner, Santa Clara, CA (US)

(73) Assignee: Multibeam Corporation, Santa Clara, CA (US)

(21) Appl. No.: 18/806,461

(22) Filed: Aug. 15, 2024

Related U.S. Application Data
(60) Provisional application No. 63/556,252, filed on Feb. 21, 2024.

(51) Int. Cl. H01J 37/302; H01J 37/02; H01J 37/317

(52) U.S. Cl. CPC H01J 37/302; H01J 37/023; H01J 37/3174

(57) ABSTRACT

Charged particle beam apparatus and methods are described herein. A charged particle beam apparatus herein includes a first column portion that has an emitter, a passively connectable power coupling coupled to the emitter, and a mechanical alignment structure coupled to the emitter, and a second column portion connected to the first column portion.

### CROSS-REFERENCE TO RELATED APPLICATIONS

This application claims the benefit from U.S. Provisional Patent Application No. 63/556,252, filed Feb. 21, 2024, which is incorporated herein by reference.

### FIELD

Embodiments relate to a modular miniature charged particle beam column that produces a beam of charged particles, and associated methods.

### BACKGROUND

Electron beam technologies are used in many manufacturing settings, most notably in semiconductor manufacturing. While electron beam techniques for lithography can enable highly customized variations on a semiconductor wafer, processing an entire workpiece using electron beam lithography can be prohibitively time consuming. Methods and apparatus are needed for faster, more cost-effective electron beam processing.

### SUMMARY

Embodiments described herein provide a charged particle beam device, comprising a first column portion, comprising an emitter; a passively connectable power coupling coupled to the emitter; and a mechanical alignment structure coupled to the emitter; and a second column portion connected to the first column portion.

Other embodiments described herein provide a charged particle beam device, comprising a first column portion, comprising an emitter; a mechanical alignment structure coupled to the emitter; and a passively connectable power coupling coupled to the emitter; and a second column portion connected to the first column portion and comprising a control assembly and a digital controller attached to the control assembly.

Other embodiments described herein provide a charged particle beam device, comprising a first column portion, comprising an emitter; a mechanical alignment structure coupled to the emitter; and a passively connectable power coupling coupled to the emitter; a second column portion connected to the first column portion and comprising a control assembly and a digital controller attached to the control assembly; and a thermal conduit coupled to the digital controller.

Other embodiments described herein provide a charged particle beam device, comprising a first column portion comprising base plate to receive a charged particle emitter at a first side of the base plate; a second column portion comprising a control assembly, the second column portion connected to the first column portion on a second side of the base plate; and a circuit board comprising a digital control circuit on the second column portion.

Other embodiments described herein provide a method of operating a charged particle beam device, the method comprising generating an analog signal using a digital signal provided to a digital-to-analog converter, the digital-to-analog converter being coupled to the charged particle beam device in a portion of the charged particle beam device that is exposed to vacuum; and applying the analog signal to a beam-control element that is coupled to the charged particle beam device in the portion of the charged particle beam device that is exposed to vacuum.

Other embodiments described herein provide a method of configuring a charged particle beam device, the method comprising adjusting a position of an emitter in the charged particle beam device while evaluating the position of the emitter optically; operating the emitter in the charged particle beam device to produce a charged particle beam from the emitter, and evaluating an attribute of the charged particle beam; and storing information relating to the attribute of the charged particle beam in a memory coupled to the charged particle beam device.

Other embodiments described herein provide a method of operating a charged particle beam device, the method comprising generating an analog signal using a digital signal provided to a digital-to-analog converter that is coupled to the charged particle beam device while the charged particle beam device is installed in a processing system; and applying the analog signal to a beam-control element of the charged particle beam device while the charged particle beam device is installed in the processing system.

### BRIEF DESCRIPTION OF THE DRAWINGS

Some example embodiments are illustrated, by way of example and not limitation, in the accompanying figures. In the figures, like reference numbers indicate like features, and features might not be drawn to scale.

FIG. 1A is a schematic cross-sectional view of a modular miniature charged particle beam column according to an example embodiment.

FIG. 1B is a schematic cross-sectional view of a modular miniature charged particle beam column apparatus according to an example embodiment.

FIG. 2A is an exploded perspective view of the charged particle beam column of FIG. 1A.

FIG. 2B is a perspective view of an upper portion of the charged particle beam column of FIGS. 1A and 2A.

FIGS. 3A and 3B are system diagrams illustrating aspects of a system that includes a plurality of modular miniature charged particle beam columns according to an example embodiment.

FIG. 4 is a method diagram illustrating a method of aligning an emitter according to an example embodiment.

FIG. 5 is a method diagram illustrating a method of preparing a column according to an example embodiment.

### DETAILED DESCRIPTION

Modular miniature charged particle beam columns are described herein that can be used for, e.g., maskless patterning of a workpiece such as a wafer, a semiconductor, optical, or optoelectronic package, an interposer, and the like. Such charged particle beam columns can be implemented as a group or array of multiple modular charged particle beam columns to allow parallel processing of a single workpiece by the multiple modular charged particle beam columns, e.g., multicolumn or multibeam processing. These modular charged particle beam columns can be described as “plug-and-play,” having features that allow for fast installation, short down-times, short mean time to repair (MTTR), and generally quick and easy deployment and replacement. The charged particle beam column can include features that reduce pump-down times and eliminate virtual leaks in a vacuum environment. Virtual leaks are sources that act to increase pressure in the vacuum environment, e.g., trapped gasses, components that volatilize or vaporize in the vacuum environment (such as chemical components of seals, coatings, or other parts), and the like. The charged particle beam column can be a modular component that simplifies installation and replacement of the charged particle beam column in a system. For example, some charged particle beam columns described herein are enhanced with features that facilitate alignment and/or calibration or other preparation.

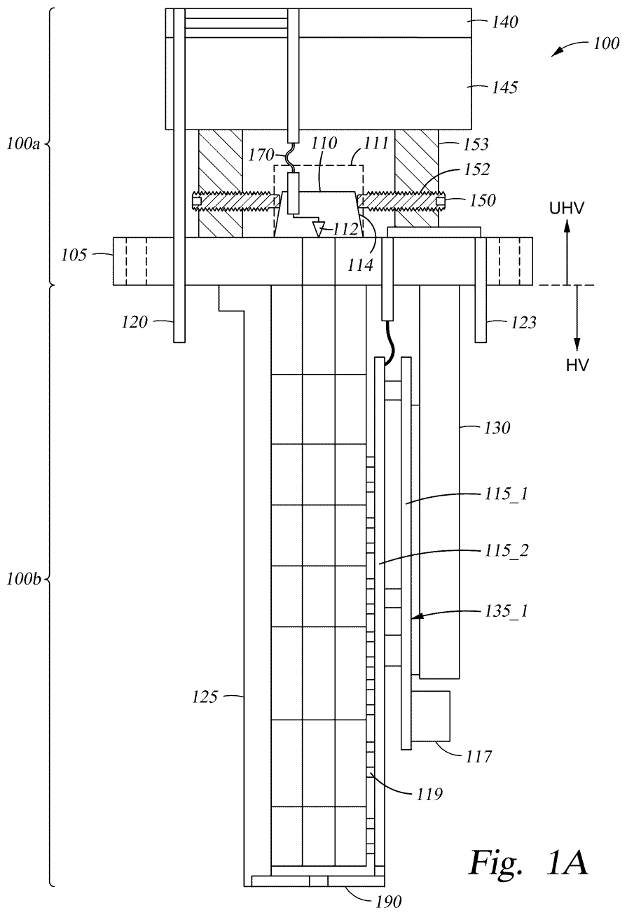

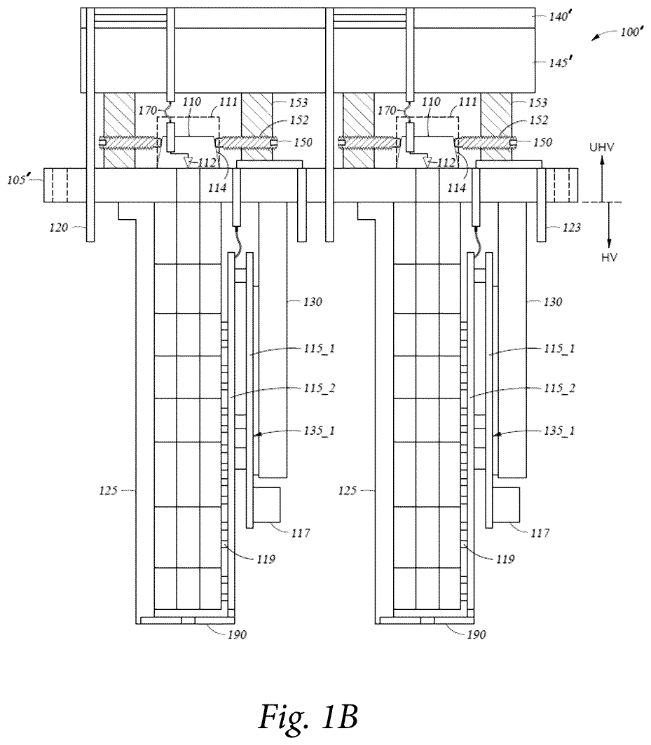

FIG. 1A is a schematic cross-sectional view of a charged particle beam column 100 according to an example embodiment. The column 100 is a modular, miniature charged particle beam column. The column 100 can have a size that enables use of multiple columns 100 arranged in a single processing chamber to process a single workpiece. In one case, nine columns 100 are arranged side-by-side in a processing chamber as a three-by-three array to act on a single 200 mm wafer, although it will be understood that more or fewer columns 100 can be arranged in a chamber and other sizes and types of workpieces can be processed. For example, in another case, 25 columns 100 are arranged side-by-side in a five-by-five array within a single processing chamber. The column 100 can have a lateral dimension, in a beam-controlling portion thereof, of about 25 mm and a length of about 125 mm, although it will be understood that the dimensions can vary.

In FIG. 1A, the column 100 includes a first column portion 100a and a second column portion 100b. The first column portion 100a includes a source of charged particles. The source can be or include an emitter 110 that emits the charged particles. The second column portion 100b corresponds to a beam-controlling portion of the column 100. The second column portion 100b includes a control assembly having one or more beam-control elements (e.g., elements that form, align, deflect, shape, and/or focus a beam of the charged particles) that form a control pathway traversed by the charged particles emitted from the emitter 110.

The first column portion 100a can correspond to an ultra-high vacuum (UHV) environment. For example, the first column portion 100a can be deployed within the UHV environment, a UHV environment can be maintained within an interior of the first column portion 100a, or both. The second column portion 100b can correspond to a high vacuum (HV) environment. The column 100 can include a base member 105 that provides a sealed interface and divides the UHV environment from the HV environment. The base member 105 is shown and described herein as a plate, and referred to subsequently as a “base plate 105,” but the base member 105 could have a shape or structure that is not a plate, as such. Although FIG. 1A illustrates the UHV and HV environments as respectively corresponding to a region above and below a lower surface of the base plate 105, during operation of the column 100 some parts of the UHV and HV environments may extend in other regions. For example, the UHV environment may extend partially into the second column portion 100b in a center region (beam region) of the column 100, while the rest of the second column portion 100b operates in the HV environment.

The emitter 110 can be an ion emitter or an electron emitter. The emitter 110 can be a thermal field emitter (TFE) that emits electrons at an emitter tip 112. The electrons pass through an opening in the base plate 105 to the second column portion 100b. The emitter 110 can be disposed in the first column portion 100a and, in operation, is located in the UHV environment, while the second column portion 100b is located in the HV environment. The base plate 105 is penetrated by electrical conductors disposed through openings in the base plate 105 and sealed to the base plate 105 using sealant materials selected to isolate the UHV and HV environments.

During operation of the column 100, the base plate 105 can maintain a pressure differential between the first column portion 100a and the second column portion 100b that is at least one order of magnitude. For example, the UHV environment can be maintained, during operation, at a first pressure, e.g., approximately 1E-9 Torr (1.3E-7 Pa) or less, while the HV environment is maintained, during operation, at a second pressure, e.g., approximately 1E-6 to 1E-8 Torr (1.3E-4 to 1.3E-6 Pa). In other cases, the UHV environment can have an operating pressure of about 1E-10 Torr (1.3E-8 Pa) while the HV environment has an operating pressure of 1E-9 Torr (1.3E-7 Pa) or more.

In another example, during operation of the column 100, the base plate 105 can maintain a pressure difference between the first column portion 100a and the second column portion 100b while the emitter 110 operates in a first pressure environment that is at or near atmospheric pressure and the second column portion is at a higher or lower pressure than the first column portion. In another example, the first column portion 100a and the second column portion 100b operate in a same pressure environment. In the case that the first column portion 100a and the second column portion 100b operate in a same pressure environment, the base plate 105 may not provide a sealed interface between the first column portion 100a and the second column portion 100b, and/or no seal may be provided between the base plate 105 and a corresponding mounting surface.

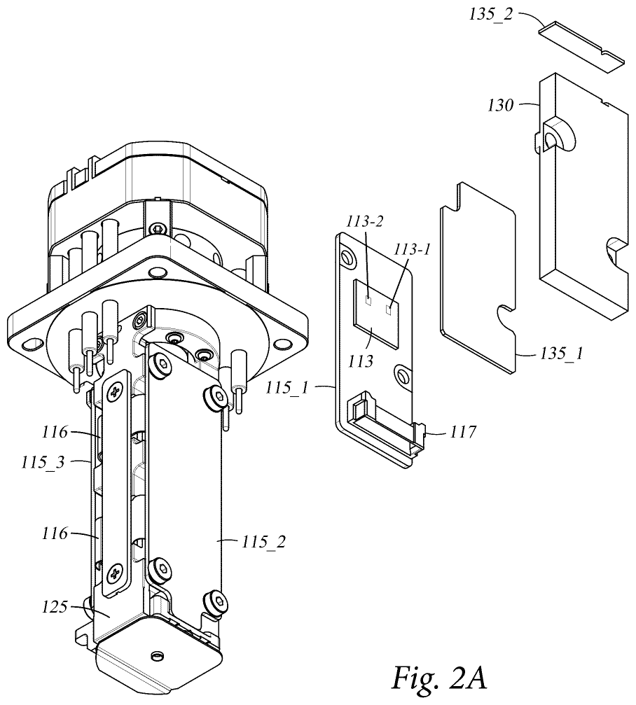

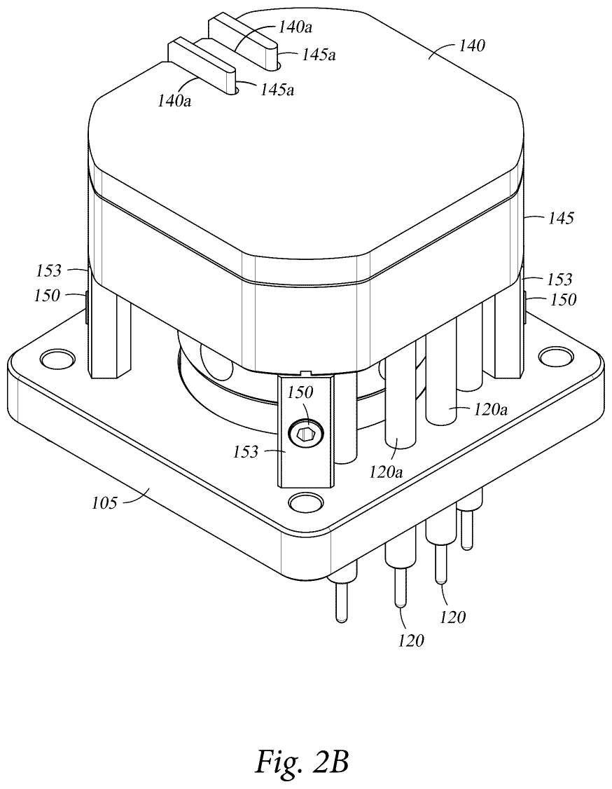

One or more components of the second column portion 100b can be controlled using digital signals. The second column portion 100b can include circuitry to convert the digital signals into analog signals that control the charged particles originating from the emitter 110 and passing through the beam-control elements of the second column portion 100b to interact with a workpiece. In one case, at least some aspects of the circuitry are implemented as a digital controller 113 (FIG. 2A). The digital controller 113 can include a digital-to-analog (D-A) converter 113-1 (FIG. 2A). The D-A converter 113-1 converts a digital signal to an analog signal. The analog signal can be provided to a beam-control element of the control assembly. The beam-control element can be used to control or modify the trajectory of the charged particles, for example to form the charged particles into a beam. The digital controller 113 is electrically connected to the beam-control elements to deliver analog signals to the beam-control elements. The digital controller 113 having the D-A converter 113-1 can be mounted in the HV environment. For example, the digital controller 113 can be mounted to the support 125 or adjacent to the column 100 in the HV environment.

A printed circuit board (PCB) 115 or a plurality of the PCBs 115, e.g., a first PCB 115_1 and a second PCB 115_2, containing circuitry for controlling the beam-control elements can be coupled to the second column portion 100b. The PCB 115 can be electrically connected to one or more beam-control elements. The one or more PCBs 115 can include, or be connected to, the digital controller 113, which can be mounted to, or adjacent to, the second column portion 100b. For example, the first PCB 115_1 can include the digital controller 113 as a part of the circuitry of the PCB 115_1 or as a component electrically connected to the PCB 115_1.

The digital controller 113 can be a component that is electrically connected to the PCB 115, or included in circuitry of the PCB 115. The digital controller 113 can be wired to the PCB 115, such that the digital controller 113 is a component located adjacent to the PCB 115 and physically connected to the PCB 115 only by wiring. Alternately, the digital controller 113 can be mounted to the PCB 115 and connected to circuits of the PCB 115 by soldering, wiring, or other electrical contact method. The digital controller 113 can be disposed proximate to the beam-control elements. By providing the digital controller 113 close to or local to the beam-control elements, a distance traveled by the analog signals between the digital controller 113 and the beam-control elements can be kept short, thus reducing opportunities for signal loss or noise to affect the analog signals. Such assemblies also enable the digital controller 113 to remain with the column 100 in the event the column 100 is removed from one system and installed in another system, or in the event the column 100 is operated in a test system and then moved to a production system.

The beam-control elements of the second column portion 100b can be included in a column structure that includes a support 125 that maintains structural integrity and operational relationships of the components of the second column portion 100b. The beam-control elements can be coupled with or mounted on the support 125. The support 125 can be or include a bracket that extends along an axis of the second column portion 100b. The support 125 can be coupled to the base plate 105 or can be part of the base plate 105. The column structure can include the support 125, the beam-control elements, and the digital controller 113, which can include the D-A converter or can be coupled to a D-A converter as a separate component or circuit.

Various configurations and combinations of the PCBs 115 can be implemented. One or more PCBs 115 can be mounted to the support 125. Merely by way of example, FIG. 2A illustrates three PCBs 115 coupled to the support 125, with first and second PCBs (115_1 and 115_2, one stacked on the other) coupled to one side of the support 125 and a third PCB 115_3 coupled to an opposite side of the support 125. The PCBs 115 can be electrically and physically connected together and/or connected to other components using, e.g., direct contacts therebetween, ribbon cables, and the like. FIG. 2A shows two ribbon cables 116 connecting the second PCB 115_2 to the third PCB 115_3. The second PCB 115_2 can be mounted to the support 125 and the first PCB 115_1 can be mounted to the second PCB 115_2. In another example, the first PCB 115_1 and the second PCB 115_2 can be individually mounted to the support 125. In another example, one or more of the PCBs 115 can be attached to a part of the second column portion 100b other than the support 125.

The column 100 can have one or more analog signal-controlled beam-control elements that are calibrated. By including the digital controller 113 as part of the column 100, as shown above, the calibration can be made more accurate, precise, and persistent as compared to a case in which the digital controller 113 is separate from the column 100. A memory, e.g., a nonvolatile memory, can be provided on one or more of the PCBs 115 in the second column portion 100b and used to store calibration information, identification information, installation information, test information, any combination thereof, and/or other information. Calibration information can include settings applied to the analog beam-control elements of the column 100 that resulted in a beam condition within a tolerance. Test information can include beam conditions recorded during one or more tests of the column 100. Identification information can include an identity of the column 100, for example a numeric or alphanumeric code. The identification information can include a unique identifier to distinguish the column from other columns, e.g., from other visually identical columns. Installation information can include date information and identity of installer. By including the digital controller 113 and/or the memory as part of the column 100, the column 100 can be made more modular by reducing the number of external components that are not “local” to the column 100 (e.g., by avoiding the need for an external or off-column digital controller 113 and/or memory). The column 100 having the digital controller 113 and/or memory thereon can be pre-calibrated in a test environment or test system prior to installation in a production system, which advantageously enables reductions in down time, MTTR, and the like when installing or changing the column 100 in the production system. In one example, power couplings of the first column portion 100a can provide power in a quick connection-disconnection structure to all components of the column 100. In another example, power couplings of the second column portion 100b can provide power in a quick connection-disconnection structure to all components of the column 100. In another example, power and signal couplings of the second column portion 100b can provide power and signals in a quick connection-disconnection structure to all components of the column 100. The construction of the column 100 provides for quick installation of a complete modular, miniature charged particle column into a test system for testing or calibration, quick removal of the column from the test system, and quick installation of the column into a production system. It will be appreciated that such advantageous effects are multiplied when a plurality of the columns 100 is installed in a system.

One or more of the PCBs 115 can have a connector 117 thereon, which can provide low voltage supply and/or digital control connections. The connector 117 can be a ribbon cable connector, or other type of connector to supply power and/or control signals to the PCBs 115. Interconnection of the PCBs 115, as described above, enables the connector 117 to provide and/or control signals to all of the PCBs 115.

One or more of the PCBs 115 can have electrical connectors 119 (FIG. 1A). For example, one or more of the PCBs 115 can have electrical connections, made by the connectors 119, to beam-control elements of the second column portion 100b. The connectors 119 can be resilient electrical contacts, such as pogo pins or the like, that extend between the second PCB 115_2 and beam-control elements of the second column portion 100b. Using resilient electrical contacts as electrical connectors enables application of compressive force between contacts of the PCBs 115 and contacts of the second column portion 100b to ensure that reliable electrical contact is maintained.

Heat removal from heat-generating components of one or more of the PCBs 115 can be enhanced by a heat transfer member, e.g., a thermal conduit 130, which can be a heat sink. For example, the second column portion 100b can include the thermal conduit 130, which can be thermally coupled to the base plate 105 to conduct heat to the base plate 105. The thermal conduit 130 is disposed in thermal communication with circuitry or electronics on one or more of the PCBs 115, and heat generated by the circuitry or electronics is conducted from the circuitry through the thermal conduit 130 to the base plate 105. The base plate 105 can be thermally conductive, or can have a thermally conductive part or member, and can be thermally coupled to a cooling system that removes heat from the base plate 105. The thermal pathway from circuitry of the PCBs 115 to a cooling system, thus configured, removes heat from the PCBs 115.

In one example, the thermal conduit 130 is fixed to the support 125, e.g., by one or more fasteners that engage the support 125. FIG. 2A shows the first PCB 115_1 and the second PCB 115_2, each having generally planar shape, in parallel orientation and interposed between the thermal conduit 130 and the support 125. In this case, the support 125 also has a generally planar shape and is disposed in perpendicular orientation to the first and second PCBs 115_1 and 115_2. In another example, the thermal conduit 130 is fixed to one or more PCBs 115.

A thermal coupling 135 or a plurality of thermal couplings 135 can be provided to enhance heat transfer. For example, referring to FIG. 2A, a first thermal coupling 135_1 can be provided between, and in thermal communication with, each of the first PCB 115_1 and the thermal conduit 130. The first thermal coupling 135_1 can be a solid material, an elastomer, or the like, that is thermally conductive, compliant, and vacuum-compatible. The first thermal coupling 135_1 can be a material that is electrically insulating. The first thermal coupling 135_1 can be a material such as a filled silicone that exhibits low outgassing under vacuum. As also shown in FIG. 2A, a second thermal coupling 135_2 can be provided between, and in thermal communication with, each of an end of the thermal conduit 130 and a lower surface of the base plate 105. The second thermal coupling 135_2 can be made of the same material as the first thermal coupling 135_1 or they can be made of different materials. The first thermal coupling 135_1 can be in direct physical contact with one or both of the first PCB 115_1 and the thermal conduit 130. The second thermal coupling 135_2 can be in direct physical contact with one or both of the thermal conduit 130 and the base plate 105.

A first conductor 120 or a plurality of the first conductors 120 and a second conductor 123 or a plurality of the second conductors 123 can be disposed through the base plate 105. In this case, the two types of electrical conductors supply significantly different voltages for different purposes on the column 100. For example, the second conductors 123 can supply a lower voltage than the first conductors 120. The first conductors 120 and the second conductors 123 penetrate the base plate 105 to provide power while maintaining isolation of the UHV and HV environments.

The column 100 has power couplings that are passively connectable to power couplings of a processing chamber or a test chamber. In an example embodiment, one or more pins and/or one or more plugs attached to the column 100 are disposed to plug into or couple to corresponding electrical contacts provided in one or more mounting surfaces of the processing chamber or test chamber when the column 100 is inserted into, or coupled to, the processing chamber or test chamber. The passively connectable couplings of the column 100 enable the column 100 to be plugged into either a processing chamber or a test chamber having corresponding electrical contacts such that the column 100 can be easily transferred between a processing chamber and a test chamber. For example, using such structures, a column like the column 100 can be installed in a test chamber for testing and/or calibration, removed from the test chamber after testing and/or calibration, and then installed in a processing chamber, merely by plugging the column in, and unplugging the column from, either chamber.

In an example embodiment, one or more first conductors 120 and/or one or more second conductors 123 can be passively connected to a mounting surface, such as a lid, ceiling, mounting plate, or other surface of a processing chamber or a test chamber. For example, one or more first conductors 120 and/or one or more second conductors 123 can plug in to corresponding electrical contacts provided in a mounting surface when the column 100 is inserted into, or coupled to, a processing chamber. For example, a plurality of the first conductors 120 and/or the second conductors 123 can be substantially rigid, and extending in an insertion direction of the column 100 such that all of the plurality of first conductors 120 and/or the second conductors 123 plug in to corresponding electrical contacts when the column 100 is coupled to the processing chamber. The connector 117 of the PCB 115 can also be passively connectable. In one example, the first conductors 120, the second conductors 123, and the connector 117 all connect to corresponding electrical contacts of the processing chamber when the column 100 is inserted into the processing chamber. In another example, the connector 117 is not passively connectable, but the first and second conductors 120 and 123 are passively connectable. For example, the mounting surface of the processing chamber can have an opening to receive the second column portion 100b, and a plurality of electrical contacts surrounding the opening to receive at least one first conductor 120 and at least one second conductor 123. The base plate 105 can be mounted to the mounting surface of the chamber using fasteners. Seal members can be disposed between the mounting surface and the base plate 105 to isolate an interior of the chamber.

In an example embodiment, the passively connectable power coupling provides power connections (e.g., one or more first conductors 120 and/or one or more second conductors 123) on a second column portion side (e.g., HV side in FIG. 1A) of the column 100 for supplying all power to the column 100. In an example embodiment, the passively connectable power coupling provides power connections and signal connections (e.g., one or more first conductors 120, one or more second conductors 123, and one or more connectors 117) on the second column portion side of the column 100 for supplying all power and signals to and from the column 100.

The first column portion 100a can include conductors to supply a voltage to the emitter 110. The conductors can include wiring traces in a wiring board (WB) 140 (FIG. 1A), which can be a printed wiring board. The WB 140 can provide power, e.g., a high voltage, to the emitter 110.

The first conductors 120 can be electrically connected to conductors of the WB 140 using a pin-and-receptacle arrangement. For example, each first conductor 120 can terminate in a pin structure, the WB 140 can have a plurality of corresponding receptacle structures, and the WB 140 can be electrically connected to the first conductors 120 by placing the WB 140 on the first conductors such that the pin structures engage and electrically connect with the receptacle structures.

Electrical connections can be made between the second column portion 100b and the WB 140 by the first conductors 120. In other cases, one or more electrical connections to or from the WB 140 can be made using a flexible power conductor 170, which can be a wire, a flexure, a pogo pin, a conductor that is compliant in one or more specific degrees of freedom, or another suitable compliant connector. In one example, the flexible conductor 170 is not a wire and no discrete wires are used to route high voltage connections. The flexible power conductor 170 can be coating-free. For example, the flexible power conductor 170 can be free of polymeric coatings or polymeric insulation that can cause a virtual leak in a vacuum environment. Electrical connections between the WB 140 and the emitter 110 can include conductive pins that are received in receptacles in the WB 140.

The first column portion 100a can include an electrically insulating member between the WB 140 and the base plate 105. For example, the first column portion 100a can include an insulating cap 145 that is interposed between the base plate 105 and the WB 140. The emitter 110, the insulating cap 145, and the WB 140 can be stacked in sequence on the base plate 105, with the insulating cap 145 disposed between the base plate 105 and the WB 140. The WB 140 can have a shape that generally corresponds to a shape of the adjacent face of the insulating cap 145. For example, the WB 140 and the insulating cap 145 can have a generally octagonal shape or a rectangular or square shape which can have the corners relieved to provide access to mounting fasteners for mounting the base plate 105 to a mounting surface. The insulating cap 145 can be spaced apart from the base plate 105, e.g., by mounting lugs, legs, standoffs or the like, and the emitter 110 can be between the insulating cap 145 and the base plate 105.

The first conductors 120 can pass through the base plate 105 and the insulating cap 145 to supply power to the WB 140. Electrical connections between the WB 140 and the emitter 110 can include conductive pins that pass through the insulating cap 145 and are electrically connected to the WB 140. Electrical connections from the second column portion 100b to the emitter 110, e.g., portions of the conductors 120 and 123 that are on the UHV side of the base plate 105, can be free of individual or point-to-point wires. Electrical connections from the second column portion 100b to the emitter 110 can be free of flexible wires with polymeric insulation in the UHV region of the column 100.

An alignment screw 150 or a plurality of the alignment screws 150 can be provided to adjust an alignment, location, or placement of the emitter 110. For example, an alignment screw 150 or a plurality of the alignment screws 150 can be provided to mechanically align and register the emitter 110 in one or more of X-Y, X-Z, and Y-Z planes, where the X-Y plane is parallel to a major plane of the base plate 105 and the Z axis is normal to the X-Y plane and substantially parallel to the emitted particle beam. Adjusting the alignment screw 150 (by rotating the same) can cause the tip of the alignment screw 150 to move forward or backward, e.g., in the X-Y plane or approximately in the X-Y plane. The flexible power conductor 170 can flex to accommodate movement of the emitter 110, e.g., lateral movement in the X-Y plane or approximately in the X-Y plane, when the alignment screw 150 moves the emitter 110.

The alignment screws 150 can be arranged alongside the emitter 110, between the base plate 105 and the insulating cap 145. The emitter 110 can be disposed in a housing 111, which is a member of the first column portion 100a. The housing 111 can be or include an electrically non-conductive and magnetically non-susceptible material. Where such a housing 111 is used, the alignment screw 150, or plurality thereof, are disposed in contact with the housing 111, for example by engagement with a threaded support 153 that holds the alignment screw 150, or plurality thereof, in radial orientation against the housing 111. In one example, four of the alignment screws 150 are provided as two opposed pairs of the alignment screws 150. In another example, three of the alignment screws 150 are provided to oppose each other. For example, three of the alignment screws 150 can be arranged with approximately 120 degrees between them.

One or more of the alignment screws 150 can work in concert with other structures of the first column portion 100a to slide and/or tip (or angle) the emitter 110. For example, the emitter 110 or the housing 111 can have a sloped feature or ramp 114 that, when engaged by the alignment screw 150, causes the emitter 110 to be moved toward the base plate 105. The alignment screws 150 can also work in concert with other structures of the first column portion 100a to maintain placement of the emitter 110 at a center of the first column portion 100a. The alignment screws 150 can also work in concert with other structures of the first column portion 100a to maintain electrical contact between the emitter 110 and the base plate 105 where the emitter 110 contacts the base plate 105, for example using the ramp 114 described above to convert radial force of the alignment screws 150 partially to downward force.

The second column portion 100b can be provided with a detector 190. The detector 190 can be mounted to an end of the support 125, i.e., at an end opposite the base plate 105. The detector 190, in various examples, detects secondary electrons or ions, and/or backscattered electrons or ions for, e.g., calibration, inspection, metrology, or localized process monitoring. The digital controller 113 can include an analog-to-digital (A-D) converter 113-2 (FIG. 2A) to convert an analog signal from the detector 190 to a digital signal. The digital controller 113 having the A-D converter 113-1 can be mounted in the HV environment. For example, the digital controller 113 can be mounted to the support 125 or adjacent to the column 100 in the HV environment.

FIG. 1B is a schematic cross-sectional view of a modular miniature charged particle beam column apparatus according to an example embodiment. By way of reference, while FIG. 1A illustrates a structure in which one base plate 105 has, among other things, the emitter 110, the insulating cap 145, the WB 140, the support 125, and the detector 190, the modular miniature charged particle beam column apparatus in FIG. 1B has a base plate 105′ that is extended (relative to the base plate 105 of FIG. 1A) to provide support for plural sets of the emitter 110, the support 125, the detector 190, and other elements so as to have a plurality of independently-controlled charged particle beam columns coupled to a single base plate 105′. Thus, the base plate 105′ can have a plurality of first column portions 100a coupled to the base plate 105′ and a plurality of the second column portions 100b coupled to the base plate 105′, each second column portion 100b corresponding to, and operatively coupled with, one of the first column portions 100a. The base plate 105′ can include respective sets of alignment screws 150 (one set for each emitter 110), wherein each set of alignment screws 150 may comprise 3 alignment screws each set having the alignment screws 150 arranged with approximately 120 degrees between them.

In FIG. 1B, an insulating cap 145′ is extended relative to the insulating cap 145 of FIG. 1A. The insulating cap 145′ in FIG. 1B is a single insulating cap that corresponds to two emitters 110. In another example (not shown in FIG. 1B), two of the insulating caps 145 of FIG. 1A can be provided such that one insulating cap 145 is provided for each emitter 110. Thus, a single insulating cap 145′ can be operatively coupled with a plurality of first column portions 100a.

In FIG. 1B, a wiring board (WB) 140′ is extended relative to the WB 140 of FIG. 1A. The WB 140′ in FIG. 1B is a single WB that corresponds to two emitters 110. In another example (not shown in FIG. 1B), two of the WB 140 of FIG. 1A can be provided such that one WB 140 is provided for each emitter 110. Thus, a single wiring board 140′ can be operatively coupled with a plurality of first column portions 100a.

Although FIG. 1B shows the base plate 105′ having two sets of the emitter 110, the support 125, the detector 190, and other elements, in another example (not shown), the base plate 105′ can have three or more than three sets of the emitter 110, the support 125, the detector 190, and other elements. In such a case, the insulating cap 145′ and/or the WB 140′ can be extended to correspond to the three or more than three sets of the emitter 110, the support 125, the detector 190, and other elements, or respective insulating caps 145 and/or WB's 140 can be provided. In general, a single base plate 105′ can support a plurality of charged particle beam column devices using one insulating cap 145′ that operatively couples with all the charged particle beam column devices and one wiring board 140′ that operatively couples with all the charged particle beam column devices. Alternately, the single base plate 105′ can be used with a plurality of insulating caps 145 that individually couple with respective charged particle beam column devices and/or a plurality of wiring boards 140 that individually couple with respective charged particle beam column devices.

FIG. 2B is a perspective view of an upper portion of the column 100 of FIGS. 1A and 2A. The structures shown in FIG. 2B can be duplicated in a plurality of columns for the apparatus of FIG. 1B. Power for the emitter 110 can be supplied through the base plate 105, i.e., from the first side of the base plate 105 to the second side of the base plate 105, using the first conductors 120. The first conductors 120 are sealed to the base plate 105 to isolate the UHV environment at the first side of the base plate 105 from the HV environment at the second side of the base plate 105. The base plate 105 can include holes that penetrate through the base plate 105, and the first conductors 120 can be disposed through the holes. In an implementation, the first conductors 120 pass through the base plate 105, are insulated from the base plate 105, and are sealed to the base plate 105.

The first conductors 120 can be at least partially covered with an insulating material. The first conductors 120 can include straight electrically conductive rod portions surrounded by a cylindrical electrical insulator 120a formed of a non-conductive, non-volatile, and non-magnetically susceptible insulating material, e.g., a ceramic. The rod portions can be bonded and sealed to the surrounding insulating material. For example, the rod portions can be bonded and sealed to the surrounding insulating material by brazing or by epoxy bonding using a low outgassing epoxy such as TorrSeal.

The insulator 120a can extend through corresponding cylindrical holes in the base plate 105 (refer to the inset in FIG. 2B). The insulator 120a can be bonded and sealed to the base plate 105. In one example, the insulator 120a is bonded and sealed to the base plate 105 by brazing or by epoxy bonding using a low outgassing epoxy, e.g., TorrSeal. In another example, the base plate 105 is or includes titanium, the insulator 120a is treated with a metal on a surface of the insulator 120a that faces sidewalls of the holes, and the base plate 105 is brazed to the metal-treated insulator 120a so as to provide a vacuum seal where the first conductors 120 penetrate the base plate 105. The metal treatment on the surface of the insulator 120a can be applied using any suitable method to coat the surface of the insulator 120a. Such methods can include vapor deposition, painting, spraying, and the like. The second conductor 123 can have a same or similar structure as the first conductor 120, such that the second conductor 123 is at least partially covered with an insulating material that is bonded and sealed to the base plate 105. FIG. 1A shows the first conductor 123 being coupled to the second PCB 115_2 by a conductor that passes across the upper surface of the base plate 105 but the second conductor 123 can have a structure like that of the first conductor 120 and extend through the insulating cap 145 to connect to the WB 140. The first conductor 120 and the second conductor 123 can each connect to the WB 140 by the pin-and-receptacle arrangement described above. The first conductor 120 and the second conductor 123 can each pass through through-holes in the insulating cap 145. For example, through-holes in the insulating cap 145 may have a size sufficient to allow the first conductor 120 and the second conductor 123 (and their surrounding cylindrical insulators) to pass freely through the insulating cap 145, e.g., in a non-interference fit.

FIG. 2B shows a plurality of supports 153 and corresponding alignment screws 150. The supports 153 extend between the base plate 105 and the insulating cap 145. The WB 140 and the insulating cap 145 can be fastened to the supports 153. The supports 153 include threaded holes (not shown in FIG. 2B; see threaded holes 152 in FIG. 1A) through which the alignment screws 150 are deployed in a radial direction of the emitter 110 or the housing 111 (FIG. 1A) to contact the emitter 110 or the housing 111. As described above, the supports 153 here are disposed around the emitter 110 to enable four alignment screws 150 to be deployed in pairwise opposition, each support 153 at a 90° angular displacement from each neighboring support 153. The supports 153, in this case, are co-located with mounts for the base plate 105 at the relieved corners of the insulating cap 145 and WB 140 to provide access to adjust the alignment screws 150, and to mount and unmount the base plate 105. Co-locating the mounts and the alignment screws 150 simplifies structure of the first column portion 100a.

The insulating cap 145 can include a projecting insulating member 145a or a plurality of projecting insulating members 145a that project through the WB 140. The projecting insulating member 145a can have the shape of a wall. The WB 140 can have slots or openings penetrating therethrough in locations corresponding to the projecting insulating members 145a. Each projecting insulating member 145a can be disposed relative to conductors in the WB 140, e.g., conductors that carry high voltages, so as to provide additional electrical isolation between adjacent conductors. The projecting insulating members 145a can help to electrically isolate adjacent high-voltage conductors from each other to reduce interactions, e.g., arcing or cross-talk, between the adjacent high-voltage conductors.

The insulating cap 145 can be made of a non-volatile, electrically non-conductive, and magnetically non-susceptible material. The insulating cap 145 can include, or can be made of, a ceramic material, such as aluminum oxide or another metal oxide. The insulating cap 145 can be a monolithic ceramic structure, or a composite or alloy ceramic structure, and the projecting insulating members 145a can be ceramic members that are integral with the monolithic ceramic structure. The projecting insulating members 145a can be formed of a same material as the insulating cap 145. The insulating cap 145 and one or more projecting insulating members 145a can be formed as a monolithic unit, e.g., a machined monolithic ceramic unit.

### Beam-Control Elements—

FIG. 1A schematically illustrates beam-control elements in the second column portion 100b. The beam-control elements of the second column portion 100b can be held by the support 125.

The second column portion 100b can include a first control element and a control focusing element. The first control element can form the charged particles into a beam in the second column portion 100b. The second control element can be or include an Einzel lens. The second control element can be or include a three-element Einzel lens, with first and third elements being operated at ground voltage while a second (center) element is operated at a high negative voltage to direct a beam onto the workpiece, e.g., a wafer. Either of the first or second control elements can focus the beam to a desired size. The second column portion 100b can include beam-control elements that operate at from 5 keV to 50 keV. The beam-control elements can be spaced apart from each other by more than 1 mm. One or more beam-control elements can operate at voltages of approximately 10 kV to 12 kV. In an example, the beam-control elements do not include silicon micro-electromechanical systems (MEMS) elements.

One or more beam-control elements can be electrostatic elements. The beam-control elements can include one or more electrostatic octupoles for beam deflection. An octupole electromagnetic field can be configured to induce azimuthally-varying third-order deflections to the trajectories of charged particles passing through an 8N-pole element. A shaped beam, such as a square beam, can formed at the surface of the workpiece by controlling the excitation of the 8N poles. The 8N-pole element can be magnetic or electrostatic. Additional examples of beam control are set forth in U.S. Pat. No. 8,242,457, which is incorporated herein in its entirety.

The support 125 can extend in a direction normal to a sealing surface of the base plate 105 and can have a length sufficient to support all of the beam-control elements. The support 125 can also have the PCB 115 or a plurality of the PCBs 115 affixed thereto. The PCB 115, e.g., the second PCB 115_2, can extend to at least partially cover one or more of the beam-control elements. The PCB 115, e.g., the second PCB 115_2, can extend to at least partially cover all of the beam-control elements. All signals provided to the beam-control elements can be provided from one or more of the PCBs 115. All signals provided to the beam-control elements can be provided by the connectors 119 (which can be, e.g., resilient electrical contacts such as pogo pins or the like, as described above) from one or more of the PCBs 115.

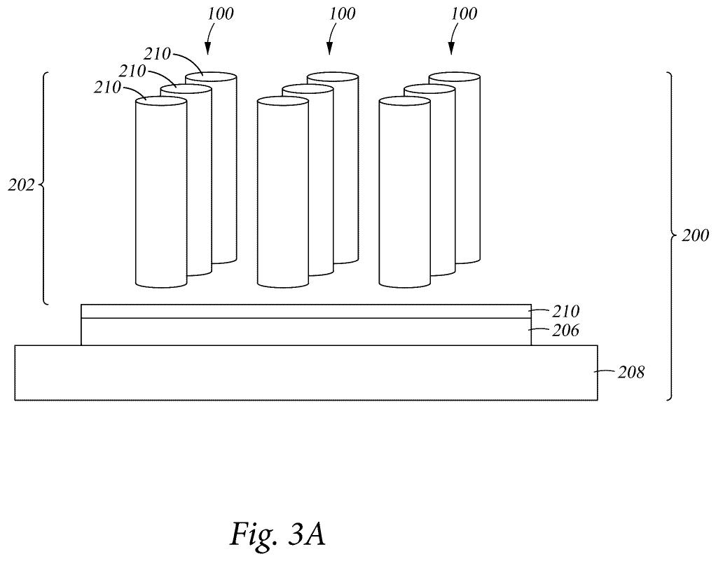

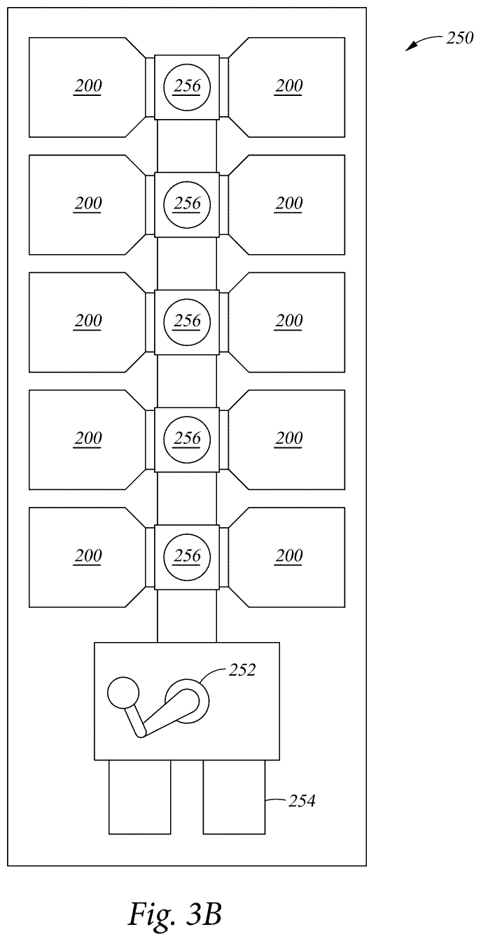

FIGS. 3A and 3B are system diagrams illustrating aspects of a system that includes a plurality of modular miniature charged particle beam columns according to an example embodiment.

Referring to FIG. 3A, a system 200 for processing a workpiece can include a plurality of the columns 100, e.g., arranged in an array 202. The plurality of columns 100 can all operate on a single workpiece 210, e.g., a wafer, that is placed in the system 200. For example, as shown in FIG. 3A, nine columns 100 can be arranged in a 3×3 array 202 to operate on the workpiece 210, which may be, e.g., a 200 mm wafer. The columns 100 in the array 202 can operate in concert, e.g., write in parallel, on the same workpiece 210. The system 200 can include a chuck 206 upon which the workpiece 210 is mounted while the workpiece 210 is operated on in the system 200. The system can include a workpiece positioning system 208 that moves the chuck 206 relative to the array 202.

Referring to FIG. 3B, a cluster tool 250 can include a plurality of modules each including the system 200, each of said systems 200 including a plurality of the columns 100 and each operating on a respective workpiece 210. The cluster tool 250 can include one or more of a workpiece handling system 252, a workpiece loading/unloading system 254, and one or more workpiece transport systems 256. A plurality of the columns 100 can be provided for a processing chamber of each system 200. As such, the cluster tool 250 can include a plurality of the processing chambers each including a plurality of the columns 100. The modular nature of the small charged particle devices described herein enables use of multiple such devices in a processing system because the devices can be easily installed and removed, with electrical connections being passively established when the device is inserted into the processing system. Such devices can also be transported between a test or calibration system and a processing system because all controls for each device are local to the device and can be transported with the device between systems. For example, the PCBs 115, which have memory circuits, can store calibration information developed for a device in a calibration system, for use in a production system.

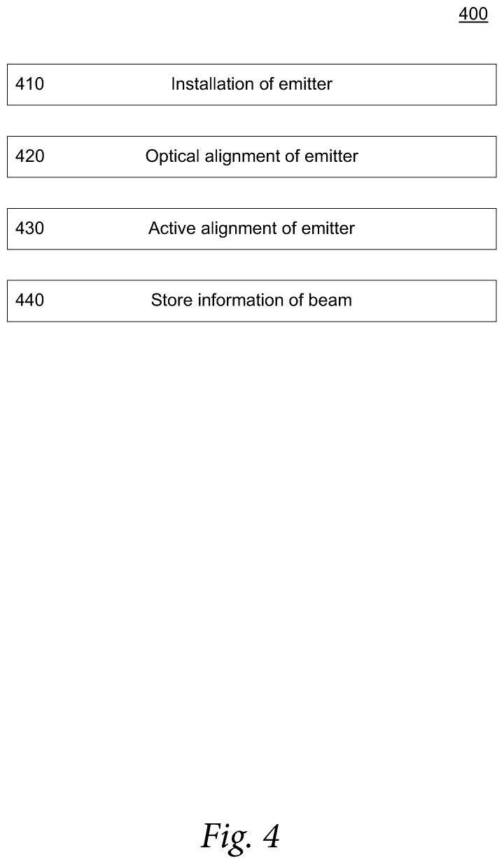

FIG. 4 illustrates a method of aligning an emitter 110 according to an example embodiment. The method 400 includes an operation 410 of installing or replacing the emitter 110 in the column 100 to place the emitter 110 in an operating position.

The method can include, after the emitter 110 is installed, an operation 420 of optically aligning the emitter 110 can be performed. Optically aligning the emitter 110 can include examining a tip of the emitter 110 under magnification, e.g., using a microscope, and moving the emitter 110 using one or more alignment screws 150, as described above. The operation 420 can be performed “cold,” i.e., in a state in which electrical power is not provided to the emitter 110 and/or the column 100, relying purely on optical observation of the emitter 110 position to perform the alignment. In one example, during the cold alignment, the column 100 is not installed in a vacuum chamber or processing chamber. The cold state can be a state in which the column 100 is at room temperature, e.g., 25° C., and/or atmospheric pressure, e.g., 1 atm or 760 Torr. In another example, the operation 420 can be performed with the column 100 mounted in an alignment jig or test system, e.g., a test chamber.

The method 400 can include, after the emitter 110 is installed, an operation 430 of active alignment of the emitter 110. The active alignment of the emitter 110 can include providing power and control signals to the emitter 110 with the emitter 110 in a vacuum environment, and observing charged particles emitted from the emitter 110 while the emitter 110 is operating. This “hot” (i.e., powered) alignment can include placing the column 100 in a production-like environment. The production-like environment can be a test, calibration, or alignment chamber in which vacuum levels and/or temperatures are the same as or similar to an exemplary or intended production environment of a processing chamber.

In operation 430, the active alignment of the emitter 110 can include evaluating an attribute of the beam, such as a beam current, developed by charged particles emitted from the emitter 110. Adjustments to the column 100 can be made while evaluating the attribute of the beam. For example, the beam current can be measured while moving the emitter 110 using one or more alignment screws 150. The operation 430 can include using a suitable tool or actuator to manipulate the one or more alignment screws 150 in the vacuum environment during the hot alignment.

The method 400 can include an operation 440 of storing information relating to the attribute of the beam that is evaluated in operation 430. For example, a memory, e.g., a digital nonvolatile memory, can be coupled to the column 100 (e.g., provided on one or more of the PCBs 115 in the second column portion 100b) and the information relating to the attribute of the beam can be stored in the memory. The information relating to the attribute of the beam can thus be stored local to the column 100 so as to be portable with the column 100 or on-board the column 100.

The operation 430 of hot alignment can be performed without performing the operation 420 of cold alignment.

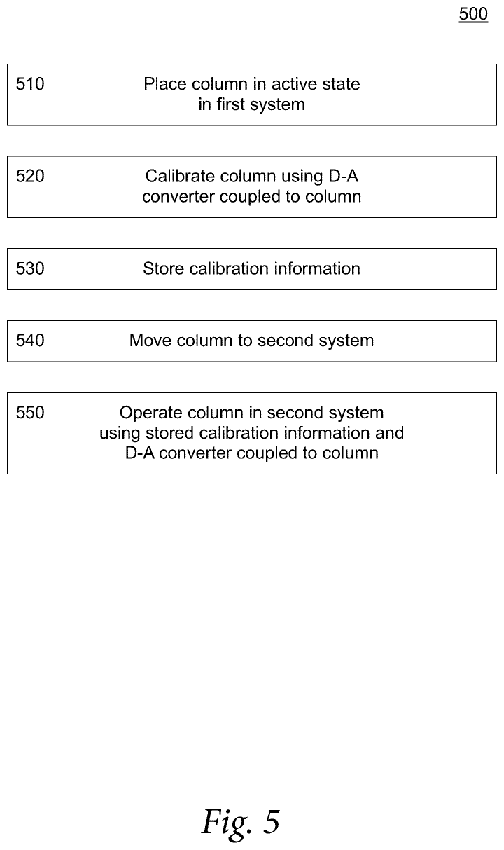

FIG. 5 illustrates a method of preparing a column 100 according to an example embodiment. The method 500 includes an operation 510 of placing the column 100 in an active state, in which power and control signals are provided. The operation 510 can be performed with the column 100 mounted in a first system. The first system can be a test, calibration, or alignment chamber in which vacuum levels and/or temperatures are the same as or similar to an exemplary or intended production environment of a processing chamber. The method 500 can be a calibration method.

The method 500 can include, after placing the column 100 in the active state (e.g., powered-up and in a test chamber at operating vacuum levels and temperatures), an operation 520 of calibrating the column 100 in the first system. The operation 520 can include providing a digital signal to the column 100, converting the digital signal to an analog signal using a D-A converter that is coupled to the column 100 (e.g., mounted, in the HV environment, to the support 125 or adjacent to the column 100 in the HV environment), and applying the analog signal to an beam-control element, such a lens, deflector, or the like, of the column 100. The operation 520 can include identifying an optimal signal, e.g., a value of an optimal digital signal or a corresponding optimal analog signal, for one or more beam-control elements of the column 100. By calibrating the column 100 using a D-A converter that is coupled to the column, better-optimized initial conditions may be achieved by a modular implementation that includes the D-A converter coupled to a beam-control element that it controls.

The method 500 can include an operation 530 of storing calibration information for the column 100. The optimal signal from operation 520 can be stored as a calibration setting. The calibration information can be stored as digital data in a memory. The calibration information can be stored off the column 100 or on-board the column 100. The calibration information can be stored in a memory that is a non-volatile digital memory mounted on or deployed in one or more of the PCBs 115, such that the stored calibration information is stored on-board the column 100.

The method 500 can include an operation 540 of removing the column 100 from the first system and installing the column 100 in a second system. The second system can be a production system. The first system can include provisions to mount a single column 100 and the second system can include provisions to mount a plurality of columns 100, e.g., in an array.

The method 500 can include an operation 550 of operating the column 100 in the second system, the operating in the second system including providing a digital signal to the D-A converter coupled to the column 100, and applying the generated analog signal to the beam-control element of the charged particle beam device while the column 100 is installed in the second system. For example, the stored calibration information from operation 540 (which can be stored in a memory mounted on or deployed in one or more of the PCBs 115) can be read as the digital signal that is then provided to the D-A converter.

The methods 400 and 500 described above can be employed for each of a plurality of the columns 100, which thus can respectively be pre-aligned and pre-calibrated. In a production environment, e.g., a fab or the like, a system employing the columns 100 can be maintained with a greater operation up-time by replacing a used column 100 with a fresh, pre-aligned and pre-calibrated column 100.

As described above, according to an example embodiment, a charged particle beam column is a small, modular device that allows for a relatively close spacing of columns to enable multiple columns to operate on a same workpiece, and enables operation in a high-throughput system such as a production system. Whereas a research and development facility may employ a single, relatively large column and may be used for iterative or one-off product development that is relatively undemanding in terms of throughput, a production environment imposes demands for high throughput and high up-time. A charged particle beam column according to an example embodiment can enable high workpiece throughput by operating multiple columns on a same workpiece, and can enable high up-time by simplifying column startup procedures and reducing repair time.

While the foregoing is directed to embodiments of the present invention, other and further embodiments of the present disclosure may be devised without departing from the basic scope thereof, and the scope thereof is determined by the claims that follow.

We claim:

1. A charged particle beam device, comprising:
a first column portion, comprising:
an emitter; and
a mechanical alignment structure coupled to the emitter;
a second column portion connected to the first column portion; and
a passively connectable power coupling coupled to the emitter.

2. The charged particle beam device of claim 1, wherein the second column portion and the first column portion are coupled at a sealed interface.

3. The charged particle beam device of claim 2, wherein the sealed interface comprises a thermally conductive plate.

4. The charged particle beam device of claim 2, wherein the passively connectable power coupling comprises a plurality of electrical conductors disposed through the sealed interface.

5. The charged particle beam device of claim 4, wherein the sealed interface comprises a plate, each of the electrical conductors is disposed through a hole in the plate, each of the electrical conductors is at least partially surrounded by an insulator, and the insulator is bonded to the plate within the respective hole.

6. The charged particle beam device of claim 1, wherein the mechanical alignment structure comprises a plurality of opposed screws.

7. The charged particle beam device of claim 1, further comprising a digital controller coupled to the second column portion, the digital controller comprises a D-A converter.

8. A charged particle beam device, comprising:
a first column portion, comprising:
an emitter; and
a mechanical alignment structure coupled to the emitter;
a second column portion connected to the first column portion and comprising a control assembly and a digital controller attached to the control assembly; and
a passively connectable power coupling coupled to the emitter.

9. The charged particle beam device of claim 8, wherein the second column portion and the first column portion are coupled at a sealed interface comprising a thermally conductive plate, and a thermal conduit thermally couples the digital controller to the thermally conductive plate.

10. The charged particle beam device of claim 8, wherein the control assembly comprises a plurality of beam-control elements, and the digital controller is electrically connected to the beam-control elements.

11. The charged particle beam device of claim 8, further comprising a D-A converter on the second column portion, an A-D converter on the second column portion, or both.

12. The charged particle beam device of claim 8, further comprising a detector on the second column portion and an A-D converter coupled to the detector to receive an analog signal from the detector.

13. The charged particle beam device of claim 8, wherein the digital controller comprises a memory to digitally store calibration information, identification information, test information, operation information, or any combination thereof.

14. The charged particle beam device of claim 10, wherein the beam-control elements are analog elements and the digital controller comprises a D-A converter electrically coupled to the beam-control elements.

15. A charged particle beam device, comprising:
a first column portion, comprising:
an emitter; and
a mechanical alignment structure coupled to the emitter;
a second column portion connected to the first column portion and comprising a control assembly and a digital controller attached to the control assembly;
a thermal conduit coupled to the digital controller; and
a passively connectable power coupling coupled to the emitter.

16. The charged particle beam device of claim 15, wherein:
the second column portion and the first column portion are coupled at a sealed interface,
the first column portion comprises a plate that forms the sealed interface, the emitter is a first emitter and is coupled to the plate, and
at least a second emitter is coupled to the plate.

17. The charged particle beam device of claim 16, wherein the passively connectable power coupling comprises a plurality of electrical conductors disposed through the sealed interface and each electrical conductor is separated from the sealed interface by an insulator having a metal-treated surface.

18. The charged particle beam device of claim 15, wherein the digital controller comprises a D-A converter.

19. The charged particle beam device of claim 18, wherein the digital controller comprises a circuit board attached to the control assembly.

20. The charged particle beam device of claim 15, further comprising a wiring board coupling the passively connectable power coupling to the emitter.
